(19) United States
(12) Patent Application Publication
(10) Pub. No.: US 2004/0004886 A1
(43) Pub. Date: Jan. 8, 2004

(54) Memory device and method for reading sequentially groups of bits from a memory device

(75) Inventors: Maurizio Perroni, Furnari (IT); Salvatore Polizzi, San Giovanni La Punta (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (IT)

(21) Appl. No.: 10/360,515

(22) Filed: Feb. 7, 2003

(30) Foreign Application Priority Data
Feb. 8, 2002 (IT) VA2002A000012

(51) Int. Cl. G11C 7/00

(52) U.S. Cl. 365/222

(57) ABSTRACT

A memory device includes an internal address bus, and first and second internal data busses. A memory receives from the internal address bus an address of memory data to be read, and transfers read memory data in blocks of N bits to the first internal data bus. An address storing circuit is coupled to the internal address bus for storing the address of the memory data to be read. An array of latches is coupled to the first internal data bus for storing the read memory data received therefrom. The array of latches includes two banks of latches. Each bank has N latches and is controlled independently from the other bank by respective commands, and each bank stores bits present on the first internal data bus upon receiving the respective commands. The second internal data bus is also connected to the array of latches. A state machine is connected to the array of latches for providing the respective commands for control thereof, and the state machine alternates the respective commands for commanding a consecutive reading of the blocks of N bits.

### FIELD OF THE INVENTION

The present invention relates in general to memory devices, and in particular, to a memory device serially read at a high bit-rate, particularly for low pin count (LPC) applications.

### BACKGROUND OF THE INVENTION

There are numerous applications for volatile and non-volatile memory devices in digital cameras, measurement instruments, etc. A functional block diagram of a known memory device is depicted in FIG. 1. The memory device comprises a standard FLASH-CORE, a storage circuit ADDLATCHED for a memory address, an array of latches DATAL for storing data read from the memory, and an internal bus BUSOUT. A state machine STATE_MACHTNE controls the array of latches DATAL, manages the data transfer operations on the internal bus BUSOUT and from an input/output bus PAD_EXT. An external timing signal or clock CK governs the execution of the sequence of operations commanded by the state machine.

When a reading operation is to be started, the state machine STATE_MACHINE generates a start read command ATD_REQ. A circuit TIMING_READ that generates timing signals for a read access to the memory receives the start read command ATD_REQ, and generates appropriate signals that are provided to the memory FLASH_CORE for carrying out the reading. The memory address to be accessed is loaded through the bus PAD_EXT in the storage block ADDLATCHED, and is sent to the memory through an address bus ADDR. The read data is placed on a data bus DBUS and is stored in the array of latches DATAL. When the state machine STATE_MACHINE provides appropriate signals EN<1:0> to the array DATAL, the latter transfers the stored data on the internal bus BUSOUT.

In the depicted example there is a data bus DBUS with 16 lines, an array of 16 latches DATAL, an internal bus BUSOUT with four lines, and a communication bus PAD_EXT with the external pins. This is a typical bus architecture in memory devices using a low pin count (LPC) protocol.

In this specification reference will be made to memory devices using the LPC protocol, which is particularly important because of its widespread use. The considerations that will be made may also be repeated for other protocols used in memory devices.

Generally, in LPC memory devices, the standard memory FLASH_CORE allows 32 bits to be read at a time. As expected by the protocol, of these 32 bits, only 8 bits are sent on the internal bus BUSOUT, in two groups of 4 bits each. During a single read operation only a portion of the available information is output.

A possible timing diagram of the device of FIG. 1, relating to a read operation with an LPC protocol, is depicted in FIG. 2. After a few initial cycles PREAMBLE during which the information necessary to the read operation are decoded, the addresses are provided to the address circuit during the cycles ADD. After that, there are two cycles TAR, TAR-Z that signal that the system bus (not depicted in FIG. 1), from that moment onwards, will be used for transferring data read from the standard memory FLASH_CORE.

A start read command ATD_REQ of the state machine STATE_MACHINE is generated on the rising edge of the external clock CK (not depicted in FIG. 2) for signaling the beginning of the TAR cycle. The circuit TIMING_READ is input with the start read command ATD_REQ and generates the timing signals for the memory FLASH_CORE relating to a read operation. The state machine STATE_MACHINE issues a command SYNC_REQ to the circuit that generates wait cycles SYNC_GEN. This circuit generates wait cycles SYNC, during which an asynchronous read is carried out within the standard memory FLASH_CORE.

The first address bit ADDR<0> selects 16 bits of the 32 bits that may be read from the standard memory. The selected 16 bits, which in the depicted example are indicated by the numbers 8112h (hexadecimal notation), are placed first on the data bus DBUS, and are then stored in the array of latches DATAL when the state machine generates the relative command EN_LOAD_DATAL. The second address bit ADDR<1> selects 8 bits of the 16 read to be transferred on the internal bus BUSOUT. In the depicted example, the numbers 2 and 1 have been selected.

The signals EN<1> and EN<0> are generated by the state machine in synchronization with the external clock, and enable the transfer of the two groups of 4 bits from the latches DATAL to the internal bus BUSOUT. From this bus they will be transferred on the external bus PAD_EXT as a low nibble DL and a high nibble DH. The successive two cycles TAR, TAR-Z establish the end of the read operation. During these two last cycles, the memory releases control of the system bus that remains available for other operations. Therefore, about twenty clock cycles, as schematically depicted in FIG. 3, are needed for reading a single byte.

When a whole page of memory data is to be read, for example a page formed by 32 bits using the memory device of FIG. 1, it is necessary to repeat four times the sequence of cycles depicted in FIG. 3. This burden noticeably limits the reading speed of the present LPC memory devices.

### SUMMARY OF THE INVENTION

An object of the present invention is to provide a method for reading sequentially data from a memory device that is particularly suited to be used with LPC type protocols, and allows a plurality of groups (pages) of a certain number N of bits to be read faster than in comparable known devices. This important result is obtained by doubling the number of latches available in the array DATAL, and by modifying the control action of the state machine STATE_MACHINE.

In a memory device according to the present invention, the array of latches DATAL is organized in two distinct banks that are independently controlled. The state machine exerts a control such that a bank of latches transfers N bits stored in it to the internal bus BUSOUT, while the other bank of latches loads other N bits stored in it to the data bus, and vice versa. The operations continue as long as the read of a whole page of bits of the memory is completed. After that, the cycles TAR, TAR-Z contemplated by the LPC protocol take place and the memory releases the system bus.

More precisely, the memory device preferably comprises a standard memory receiving through an internal address bus a memory address of data to be read, and wherein the read data are transferred to a first internal data bus in groups of a certain number N of bits. The memory device further comprises a circuit coupled to the first internal bus for storing an address received through an external bus, an array of latches is coupled to a second internal data bus for storing read data received through the first internal data bus, and a state machine controls the array of latches.

A characterizing feature of the device of the present invention is that the array of latches comprises two banks of latches, with each bank having N latches and being controlled by the state machine independently from the other bank by way of respective commands. Each bank stores the bits present on the first internal data bus when it receives a respective command. The state machine alternates the commands by commanding the reading of N bits of a group of bits to be read consecutively, and the loading of a first group of N bits in a bank while the other bank transfers the N bits stored in it to the second internal bus. This alternates between the two banks.

A method for a sequential read in accordance with the present invention comprises the following steps for each group of bits to be read:

a) reading a first group of N bits from the standard memory and transferring it to the data bus;

b) storing the first group of N bits present on the data bus in a first bank of latches of an array of latches; and

c) transferring the first group of N bits on the internal bus while a second group of N bits is read from the memory and stored in a second bank of latches of the array.

### BRIEF DESCRIPTION OF THE DRAWINGS

The different aspects and advantages of the present invention will become even more evident through a detailed description of an embodiment and by referring to the attached drawings, wherein:

FIG. 1 is a functional diagram of a memory device of the prior art;

FIG. 2 is a timing diagram of the device of FIG. 1;

FIG. 3 shows a sequence of cycles contemplated by an LPC protocol for reading a byte using the device of FIG. 1;

FIG. 4 is a block diagram of a memory device of the invention having an array of latches DATAL organized in two banks, independently controlled by the signals LOAD_DATAL_LOW and LOAD_DATAL_HI;

FIG. 5 is a basic scheme on the organization of the latches of the array with the respective command signals EN<7:0> for downloading the data stored therein;

FIGS. 6 and 7 are possible timing diagrams for the circuit of FIG. 4; and

FIG. 8 shows the sequence of cycles for a reading operation, according to an LPC protocol, in the memory device of FIG. 4.

### DETAILED DESCRIPTION OF THE PREFERRED EMBODIMENTS

To better illustrate the different features of the memory device and of the method of the present invention, reference will be made to a typical application in a system that uses an LPC protocol. More precisely, the case to be considered involves a standard memory core of a memory device that allows 32 bits to be read at a time, and the data bus has 16 lines and the output bus has 4 lines.

It is clear that this invention may be useful, even for other types of protocols, when using a different number of output pins and a different external synchronization, such as a parallel device with 8 output data lines that uses the signal OUTPUT_ENABLE as an external clock.

A sample embodiment of the memory device of this invention is depicted in FIG. 4. The device has an array of latches DATAL divided in two banks of 16 latches, with each bank being independently controlled by the state machine STATE_MACHINE.

The state machine includes logic circuits specifically for generating address reset signals RESET_ADD and address increment pulses INC_ADD and A0++, whose function will be explained below, and the commands LOAD_DATAL_LOW and LOAD_DATAL_HI for respectively loading the data read in the first and second bank of latches.

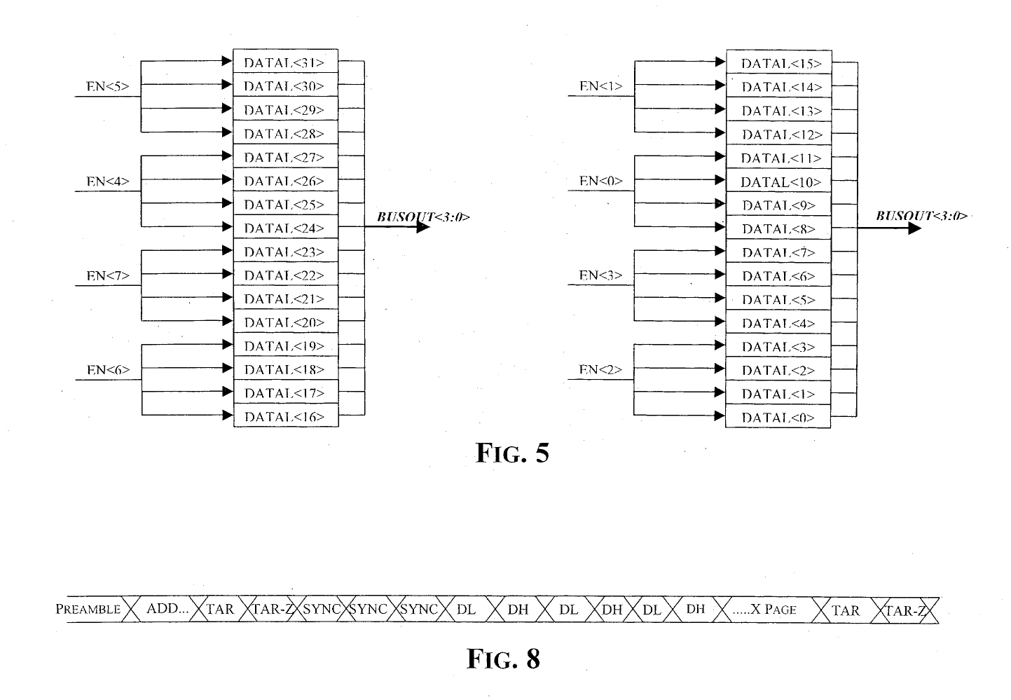

The organization of the two banks of latches is schematically depicted in FIG. 5. A first bank is formed by the latches DATAL<15:0>, and a second bank is formed by the latches DATAL<31:0>. The commands EN<7:0> generated by the state machine are provided to the latches for commanding the transfer of the bits stored in the latches on the internal bus BUSOUT. An EN command is given to four latches at a time so that at each cycle of the signal EN<7:0>, four bits are placed on the internal bus.

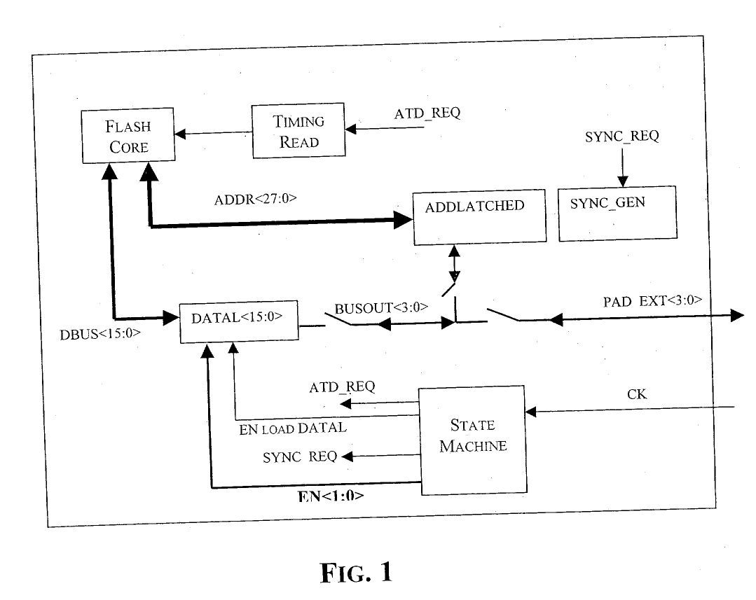

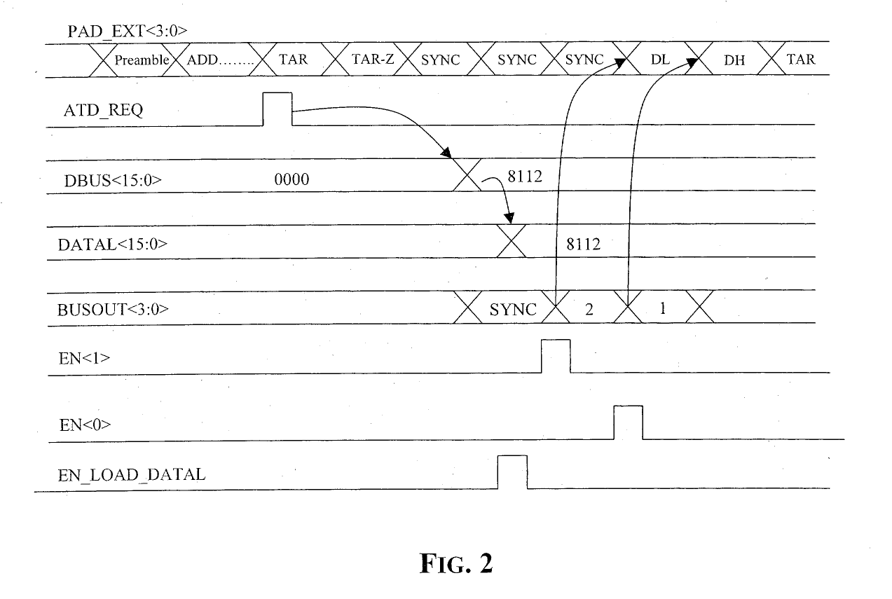

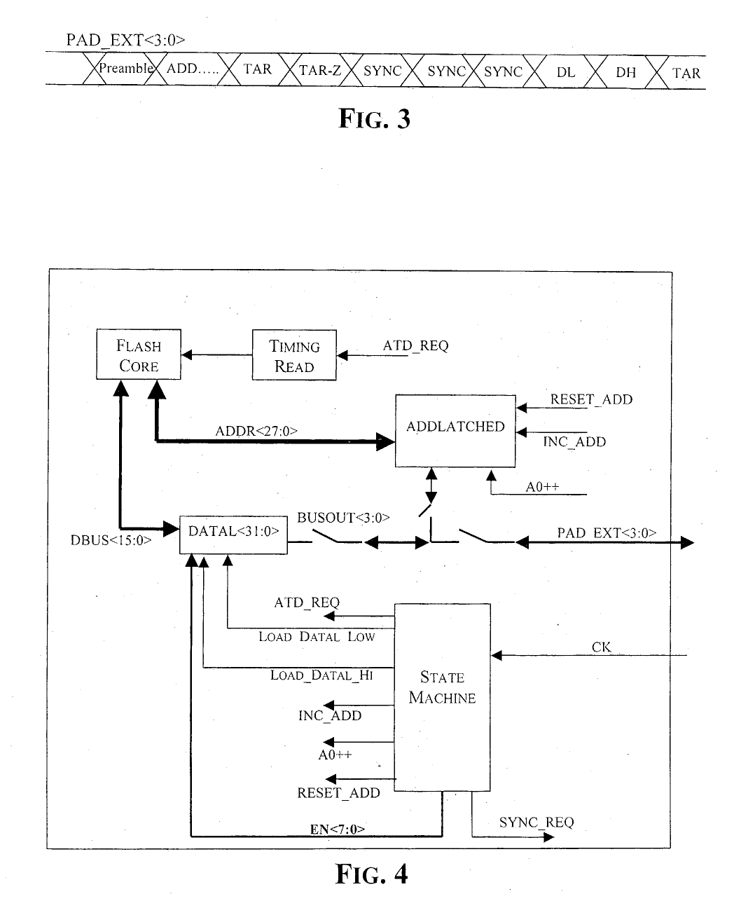

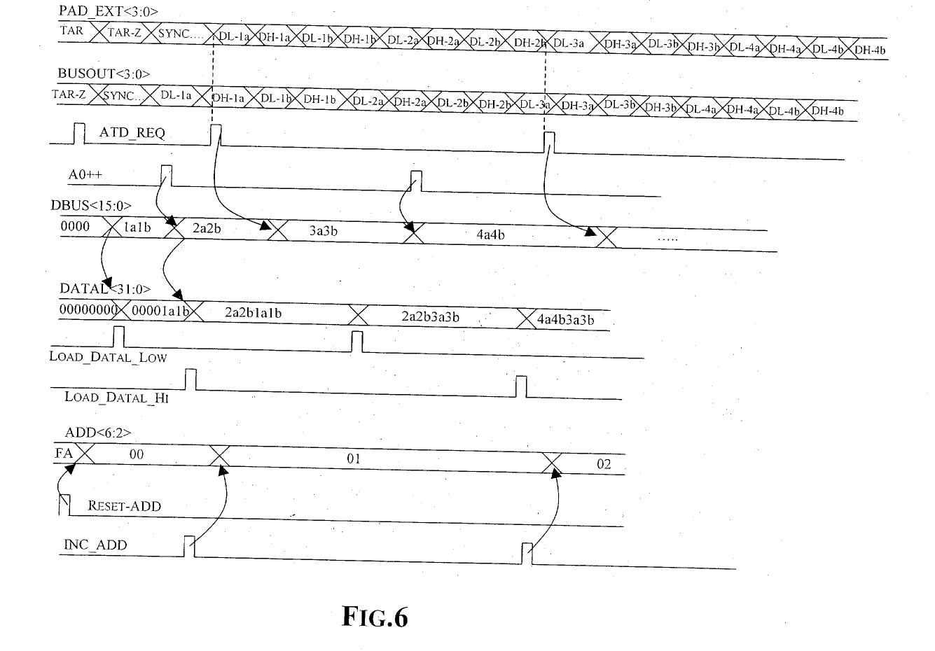

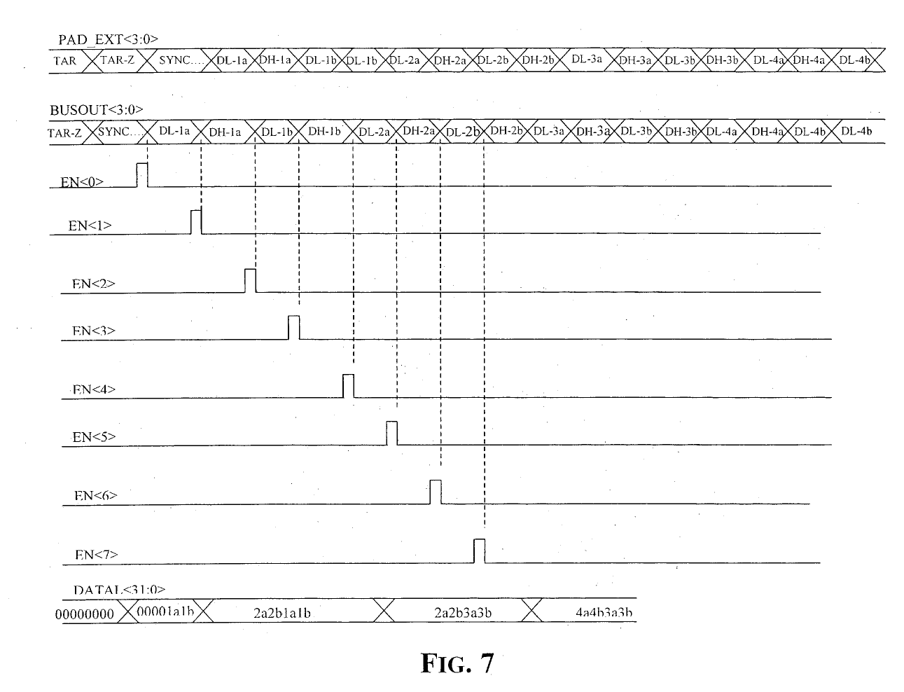

The way in which a reading is performed is shown in the timing diagrams of FIGS. 6 and 7. It is assumed that one read command per page has been decoded, and for better showing the advantages of this invention, it is assumed that a group of 128 bytes must be read consecutively from the memory. Therefore, seven address bits ADDR<6:0> are necessary for identifying each byte. The address bits ADDR<1> and ADDR<0> have the same function as in the known device of FIG. 1.

Initially, a reset pulse RESET_ADD of the seven address bits ADDR<6:0> is generated, such that the reading of the page starts from the smallest address. After the cycles, TAR and TAR-Z signal that the system bus is used by the memory, and wait cycles SYNC are generated during which the first asynchronous reading is carried out.

Then a first pulse ATD_REQ is generated that starts the reading of a group of 32 bits, identified in the diagrams of FIGS. 6 and 7 by the bytes 1a, 1b, 2a, 2b. The first 16 bits 1a and 1b, pointed by the address bit ADDR<0>, are transferred to the data bus DBUS<15:0> by the control pulse LOAD_DATAL_LOW.

Thereafter, an increment pulse A0++ of the address bit ADDR<0> is generated, and this causes the loading on the bus DBUS<15:0> of the other 16 bits (2a and 2b) of the first group of bits read. These bits are stored in the second bank DATAL<31:16> by the control pulse LOAD_DATAL_HI. Meanwhile, the first 16 bits 1a and 1b are respectively transferred as a low nibble DL and as a high nibble DH on the internal bus BUSOUT.

The signals EN<7:0>, in synchronization with the external clock CK, command the bit transfer from the array of latches DATAL to the internal bus BUSOUT. On the trailing edge of the clock that enables the generation of the first data to the output bus PAD_EXT, an increment pulse INC_ADD of addresses ADDR<6:2> is generated, and successively with a certain delay another pulse ATD_REQ is generated. In this way, a second reading is started that will produce the successive 32 bits.

The addresses of the memory locations are given by the four possible combinations among ADDR<0> and ADDR<1> with ADDR<6:2>=01h (hexadecimal). When all 16 bits stored in the DATAL<15:0> have been loaded on the internal bus BUSOUT, and thus produced on the external pads, a load pulse LOAD_DATAL_LOW is generated that updates the content of latches DATAL<15:0> with the content of the DBUS, that is, with the first part of the information relative to the second reading cycle. Meanwhile, the second bank DATAL<31:16> transfers the bits 2a and 2b stored in it to the internal bus BUSOUT.

Then an increment pulse A₀++ of the address ADDR<0> is generated for transferring to the data bus DBUS the other 16 bits 3a and 3b. Finally, the pulse LOAD_DATAL_HI commands the loading of the bits present on the data bus DBUS in the second bank of latches DATAL<31:16>.

The above described process of sequential readings continue until the whole group of 128 bytes has been read, that is, until the address ADDR<6:2>=1Fh. When the reading of whole group of bits has finished, the two cycles TAR and TAR-Z are performed signaling the end of the reading operation and the availability of the system bus to carry out other operations.

With the method and the memory device of this invention, it is possible to read a block of information formed by any number of groups (pages) of bits stored in the memory with a total number of LPC protocol cycles, as schematically depicted in FIG. 8. This is less than the total number of cycles that would be required using known memory devices. Moreover, the greater the number of groups of bits (pages) to be read from the memory, the shorter becomes the time required as compared with the time that would take with known devices.

That which is claimed is:

1. A memory device comprising
a standard memory (FLASH_CORE) receiving through an internal address bus (ADDR) an address of memory data to be read and transferring the read data on a first internal data bus (DBUS) in blocks of a certain number (N) of bits,
a circuit coupled to said internal address bus (ADDR) for storing an address (ADDLATCHED) received through an external bus (PAD_EXT),
an array of latches (DATAL) coupled to a second internal data bus (BUSOUT) for storing read data received through said first internal data bus (DBUS), and
a state machine (STATE MACHINE) controlling said array of latches (DATAL),
characterized in that
said array of latches (DATAL) comprises two banks of latches first and second, each having said number (N) of latches and being controlled by said state machine (STATE_MACHINE) independently from the other bank by respective commands first (LOAD_DATAL LOW) and second (LOAD_DATAL_HI), each bank storing the bits present on said first internal data bus (DBUS) upon receiving the respective command (LOAD_DATAL_LOW, LOAD_DATAL_HI);
said state machine (STATE MACHINE) alternating said commands first (LOAD_DATAL_LOW) and second (LOAD_DATAL_HI), for commanding the consecutive reading of said blocks of said number (N) of bits, loading a first group of (N) bits in a bank while the other bank transfers the (N) bits stored in it on said second internal bus (BUSOUT) by way of enable commands (EN<7:0>) generated by said state machine (STATE MACHINE).

2. The memory device of claim 1, characterized in that it implements a Low Pin Count (LPC) protocol.

3. The memory device of claim 1, wherein said number (N) of bits is 16 and said state machine generates eight enable commands (EN<7:0>) each enabling the transfer of the bits stored in a respective group of four latches on said second internal data bus (BUSOUT) at a time.

4. The memory device according to claim 1, wherein said state machine (STATE_MACHINE) provides to said address storing circuit (ADDLATCHED) reset pulses (RESET_ADD) and sequential increment pulses (INC_ADD, A0++) of the memory address of a block of bits to be read.

5. A method of sequentially reading of a plurality of blocks of a certain number (N) of bits stored a memory device as defined in claim 1, comprising the following steps for each block of bits to be read:
a) reading a first block of said number (N) of bits by said standard memory and transferring it on said data bus (DBUS);
b) storing said first block of bits present on said data bus in a first bank of latches of said array (DATAL);
c) transferring said first block of bits on said internal bus (BUSOUT) while a second block of said number (N) of bits is read by the standard memory and is transferred in a second bank of latches.

6. The method of claim 5, wherein the memory device is as defined in claims 3 and 4 and said plurality of blocks of bits constitutes a page of 128 bytes stored at consecutive memory addresses.
